(19) United States
(12) Patent Application Publication
(10) Pub. No.: US 2010/0109652 A1
(43) Pub. Date: May 6, 2010

(54) APPARATUS FOR CORRECTING POSITION OF A USER TRAY AND A TEST HANDLER

(76) Inventors: Hee Rak Beom, Seoul (KR); Kyeong Tae Kim, Suwon-si (KR)

Correspondence Address: KED & ASSOCIATES, LLP, P.O. Box 221200, Chantilly, VA, 20153-1200, US

(21) Appl. No.: 12/265,115

(22) Filed: Nov. 5, 2008

(51) Int. Cl. G01R 1/04

(52) U.S. Cl. 324/158.1

(57) ABSTRACT

The present invention relates to an apparatus for correcting position of a user tray including at least one first position member and at least one second position member that determine position of a user tray, a plate where the user tray is received, a first correcting unit that moves the user tray in a direction where the first position member is installed, a second correcting unit that moves the user tray in a direction where the second position member is installed, and an operating unit that operates the first correcting unit and the second correcting unit, which has a simple configuration, and moves a user tray to the accurate position, thereby reducing manufacturing costs and maintenance costs

### BACKGROUND

1. Field

The present invention relates to a test handler for supplying packaged chips to a tester and classifying tested packaged chips by grades.

2. Description

A test handler may be used to perform electrical tests on packaged chips at the conclusion of a packaging process.

The test handler performs a loading process, a testing process and an unloading process using a test tray including a plurality of containing units capable of containing packaged chips.

The test handler transfers the packaged chips to be tested from a user tray to the test tray. This is referred to as a “loading process”. The test handler performs the loading process using a plurality of picker systems. The picker system includes a plurality of nozzles that can absorb the packaged chip.

The test handler supplies the test tray containing the packaged chips to a tester. This is referred to as a “testing process”. The tester includes a hi-fix board having a plurality of sockets. The packaged chips in the test tray are brought into contact with the sockets to perform an electrical test on the packaged chips.

Further, the test handler includes a chamber system including a plurality of airtight chambers so that the tester performs an electrical test on the packaged chips even under extreme conditions of high temperature or low temperature.

The test handler transfers the tested packaged chips from the test tray to a user tray. This is referred to as a “unloading process”. The packaged chips are graded according to the test results, and the handler transfers the graded chips from the test tray to appropriate user tray based on the grading. The test handler performs the unloading process using a plurality of picker systems.

The test handler includes a stacker that can store a plurality of user trays used in the loading process and the unloading process.

FIG. 1 illustrates a stacker that stores a plurality of user trays in a test handler, and FIG. 2 illustrates a state where the position of the user tray is corrected.

Referring to FIG. 1, the stacker 100 can store a plurality of user trays C, and includes a loading stacker 101, a unloading stacker 102, a buffer stacker 103 and a transferring unit 104.

A plurality of loading stackers 101 may be installed in the main frame (not shown) of the test handler, and includes a loading stacking member 1011 and a loading plate 1012.

A plurality of user trays C containing packaged chips to be tested may be stored in the loading stacking member 1011.

The loading plate 1012 supports a user tray where the loading process is performed, and is installed in the main frame of the test handler in such a manner that the loading plate 1012 can ascend and descend.

A plurality of unloading stackers 102 may be installed in the main frame of the test handler so that a plurality of user trays containing tested packaged chips may be stored in different positions by grades according to the test result.

The unloading stacker 102 includes an unloading stacking member 1021 and a unloading plate 1022.

A plurality of user trays C containing tested packaged chips may be stored in the unloading stacking member 1021.

The unloading plate 1022 supports a user tray C where the unloading process is performed, and is installed in the main frame of the test handler in such a manner that the unloading plate 1022 can ascend and descend.

A plurality of empty user trays C may be stored in the buffer stacker 103.

The transferring unit 104 can hold the user tray C, and is installed in the main frame of the test handler in such a manner that the transferring unit 104 can move. The transferring unit 104 can be installed in the main frame of the test handler in such a manner that the transferring unit 104 move in X-axis and Y-axis directions. The transferring unit 104 also ascend and descend.

In the stacker 100, the user tray C is transferred as follows.

First, the transferring unit 104 transfers the user tray C, which contains the packaged chips to be tested, from the loading stacking member 1011 to the loading plate 1012.

Next, the loading plate 1012 elevates the user tray C, which was transferred from the loading stacking member 1011, to the position 101a where the picker system (not shown) can pick up the packaged chips to be tested in the user tray C.

Next, when the user tray C becomes empty by the completion of the loading process, the transferring unit 104 transfers the empty user tray C from the loading plate 1012 to one of the buffer stacker 103 and the unloading plate 1022.

Next, the transferring unit 104 transfers the empty user tray C from one of the buffer stacker 103 and the loading plate 1012 to the unloading plate 1022.

Next, the unloading plate 1022 elevates the user tray C, which was transferred from one of the buffer stacker 103 and the loading plate 1012, to the position 102a where the picker system (not shown) can place tested packaged chips into the use tray C.

Next, when the user tray C contains the tested packaged chips by the completion of the unloading process, the transferring unit 104 transfers the user tray C containing the tested packaged chips from the unloading plate 1022 to the unloading stacking member 1021.

The test handler can classify packaged chips by grades by repeatedly performing the above procedure.

Referring to FIGS. 1 and 2, the stacker 100 should always position the user tray C in the loading plate 1021 and the unloading plate 1022 so that the picker system (not shown) can stably perform the loading process and the unloading process.

For this, the stacker 100 includes an apparatus for correcting position of the user tray(not shown) that can move the user tray C to the accurate position in the loading plate 1021 and the unloading plate 1022.

The apparatus for correcting position of the user tray can move the user tray C in X-axis direction and Y-axis direction, thereby positioning the user tray C in the accurate position by the user tray C contacts with a first position member A and a second position member B.

However, a conventional apparatus for correcting position of the user tray separately includes a first operating unit for moving the user tray C in X-axis direction and a second operating unit for moving the user tray C in Y-axis direction, thereby making the structure complicated and increasing manufacturing costs.

Such problems get worse because a plurality of apparatuses for correcting position of the user tray is installed.

### BRIEF DESCRIPTION OF THE INVENTION

An object of the present invention is to provide an apparatus for correcting position of a user tray and a test handler that has a simple configuration and can move the user tray to the accurate position.

The present invention will not be limited to the technical objects described above. Other objects not described herein will be more definitely understood by those in the art from the following detailed description.

According to an embodiment of the present invention, there is provided an apparatus for correcting position of a user tray including at least one first position member and at least one second position member that determine position of a user tray, a plate where the user tray is received, a first correcting unit that moves the user tray in a direction where the first position member is installed, a second correcting unit that moves the user tray in a direction where the second position member is installed, and an operating unit that operates the first correcting unit and the second correcting unit.

According to an embodiment of the present invention, there is provided a test handler including a loading stacker that a plurality of user trays containing packaged chips to be tested, a loading unit that puts to-be-tested packaged chips in a test tray, a chamber system where the packaged chips are brought into contact with a hi-fix board, an unloading unit that classifies tested packaged chips contained in the test tray by grades according to the test result, an unloading stacker that stores a plurality of user trays containing tested packaged chips, and the apparatus for correcting position of a user tray installed in the loading stacker and the unloading stacker, respectively.

### BRIEF DESCRIPTION OF THE DRAWINGS

FIG. 1 is a front view illustrating a stacker that stores a plurality of user trays in a test handler.

FIG. 2 is a plane view illustrating the state where the position of a user tray is corrected.

FIG. 3 is a perspective view illustrating an apparatus for correcting position of a user tray according to the present invention and a user tray.

FIG. 4 is a perspective view illustrating the lower side of FIG. 3.

FIG. 5 is a plane view illustrating the state before an apparatus for correcting position of a user tray according to the present invention corrects the position of the user tray.

FIG. 6 illustrates the lower side of FIG. 5.

FIG. 7 is a plane view illustrating the state where an apparatus for correcting position of a user tray according to the present invention has corrected the position of the user tray.

FIG. 8 illustrates the lower side of FIG. 7.

FIG. 9 illustrates the configuration of a test handler according to the present invention.

FIG. 10 is a plane view illustrating a test handler according to another embodiment of the present invention.

### DETAILED DESCRIPTION

An exemplary embodiment of an apparatus for correcting position of a user tray according to the present invention will be described in the following with reference to attached drawings.

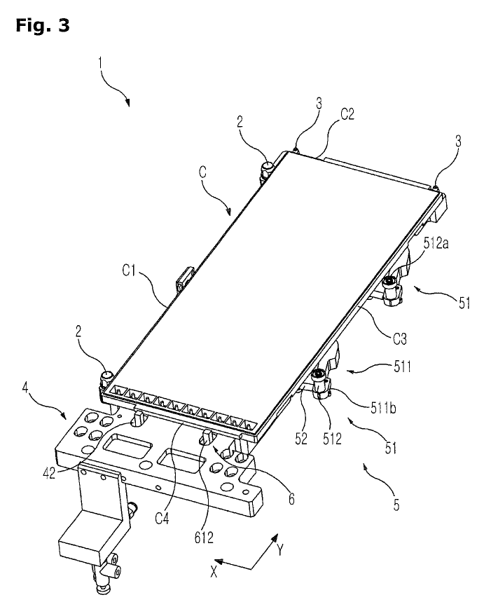

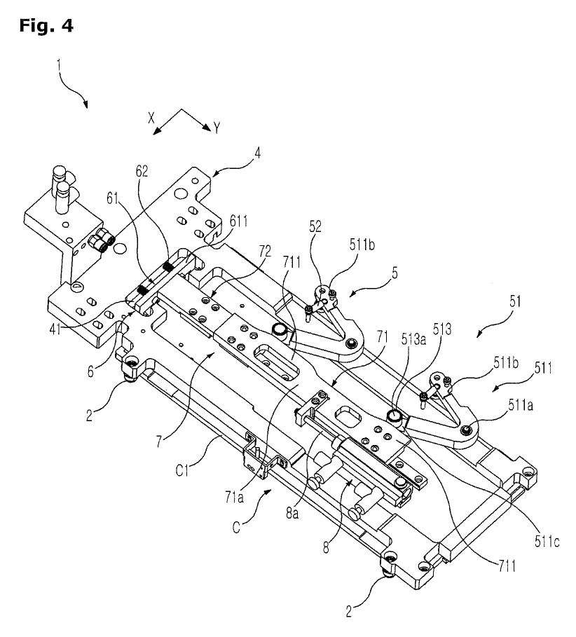

FIG. 3 is a perspective view illustrating an apparatus for correcting position of a user tray according to the present invention and a user tray. FIG. 4 is a perspective view illustrating the lower side of FIG. 3.

Referring to FIGS. 3 and 4, an apparatus for correcting position of a user tray 1 includes a first position member 2, a second position member 3, a plate 4, a first correcting unit 5, a second correcting unit 6, and an operating unit 7.

The first position member 2 determines a position of a user tray C, and can be installed at one of the plate 4 or the main frame (not shown) of a test handler.

The first position member 2 is projected to the upper side of the plate 4 by a certain length so that the first position member 2 can support the first side C1 of the user tray C.

When the first side C1 of the user tray C is supported by the first position member 2, the position of the user tray C is corrected in the direction (X arrow direction) where the first position member 2 has been installed.

The second position member 3 determines a position of the user tray C, and can be installed at one of the plate 4 or the main frame of the test handler.

The second position member 3 is projected to the upper side of the plate 4 by a certain length so that the second position member 3 can support the second side C2 of the user tray C.

When the second side C2 of the user tray C is supported by the second position member 3, the position of the user tray C is corrected in the direction (Y arrow direction) where the second position member 3 has been installed.

The second position member 3 and the first position member 2 can be installed so that the second position member 3 and the first position member 3 can support the first side C1 and the second side C2 that are perpendicular to each other.

As such, the apparatus for correcting position of the user tray 1 can move the user tray C to a accurate position by moving the user tray in such a manner that the user tray C is supported by the second position member 3 and the first position member 2. Moving the user tray C to the accurate position refers to moving the user tray C to a position where the picker system (now shown) can stably perform the loading process and unloading process.

The apparatus for correcting position of the user tray 1 may include a plurality of second position members 3 and a plurality of first position members 2. As such, the user tray C can be moved to a more accurate position.

The user tray C can be received in the plate 4, and the first position member 2 and the second position member 3 can be installed in the plate 4. The plate 4 can be formed as a tetragonal plate type.

The first correcting unit 5 is operated in such a manner that the user tray C can move in the direction (X arrow direction) where the first position member 2 has been installed. The first correcting unit 5 includes a first moving member 51 and a first elastic member 52.

The first moving member 51 is coupled to the plate 4, and can be rotated on the plate 4. The first correcting unit 5 includes at least one the first moving member 51.

The first moving member 51 can be coupled in the opposite side of the upper side where the user tray C is received in the plate 4, that is, in the lower side of the plate 4.

As such, a working area of the picker system (not shown) do not overlap in the first moving member 51, so the picker system (not shown) can stably perform the loading process and the unloading process.

The first moving member 51 includes a first moving frame 511, a first contacting member 512 and a rotating member 513.

The first moving frame 511 is coupled to the plate 4. The first moving frame 511 can be rotated around a first shaft 511a. The first moving frame 511 can be formed in the form of “>” as a whole, and can be coupled to the lower side of the plate 4.

The first contacting member 512 is coupled to one end 51b of the first moving frame 511, and can move the user tray C according to the rotation of the first moving frame 511.

The first contacting member 512 can be contacted on the third side C3 of the user tray C. As such, the user tray C can be moved to the direction (X arrow direction) where the first position member 2 has been installed by pushing the third side C3 of the user tray C.

The first contacting member 512 can be formed in such a manner that the first contacting member 512 is projected in the first moving frame 511 so that the first contacting member 512 can contact the third side C3 of the user tray C received on the upper side of the plate 4.

The first contacting member 512 can be coupled in such a manner that the first contacting member 512 can be rotated at one end 511b of the first moving frame 511.

Hence, the first contacting member 512 can rotate around the second shaft 512a when moving the user tray C, so the damage by friction of a portion where the first contacting member 512 and the user tray C contact each other can be prevented.

The rotating member 513 contacts the operating unit 7, and can receive force from the operating unit 7 for the first moving frame 511 to be rotated.

The rotating member 513 can be coupled to another end 511c of the first moving frame 511 in such a manner that the rotating member 513 can be rotated.

Hence, the rotating member 513 can rotate around the third shaft 513a when the first moving frame 511 is rotated, so the damage by friction of a portion where the rotating member 513 and the operating unit 7 contact each other can be prevented.

The first elastic member 52 elastically connects the first moving member 51 to the plate 4.

The first elastic member 52 is installed as many as the number of the first moving member 51.

One side of the first elastic member 52 can be coupled with one end 511b of the first moving frame 511, and the other side of the first elastic member 52 can be coupled with the plate 4.

As such, the first elastic member 52 pulls one end 511b of the first moving frame 511 to the plate 4 so that the first moving member 51 can move the user tray C in the direction (X arrow direction) where the first position member 2 has been installed.

The second correcting unit 6 is operated in such a manner that the user tray C can move in the direction (Y arrow direction) where the second position member 3 has been installed. The second correcting unit 6 includes the second moving member 61 and the second elastic member 62.

The second moving member 61 can move in the direction (Y arrow direction) where the second position member 3 has been installed, and move the user tray in the direction (Y arrow direction) where the second position member 3 has been installed.

The second moving member 61 can be coupled in such a manner that the second moving member 61 can be movable on the plate 4. If the operating unit 7 is coupled in such a manner that the operating unit 7 can be movable on the plate 4, the second moving member 61 can be coupled to the operating unit 7.

The second moving member 61 includes a second moving frame 611 and a second contacting member 612.

The second moving frame 611 can move in a hole 41 formed in the plate 4. The second moving frame 611 can be elastically supported by the second elastic member 62. The second moving frame 611 is formed in a tetragonal plate type as a whole.

The second contacting member 612 is formed in such a manner that the second contacting member 612 can be projected in the second moving frame 611. The second contacting member 612 can move the user tray C. The second moving member 61 may include at least one or more second contacting member 612.

The second contacting member 612 can contact the fourth side C4 of the user tray. As such, the user tray C can be moved to the direction where the second position member 3 has been installed by pushing the fourth side C4 of the user tray C.

The second contacting member 612 can be moved in a hole 42 formed on the plate 4. The second contacting member 612 can be contacted on the fourth side C4 of the user tray C received on the upper side of the plate 4 by penetrating the hole 42.

The second elastic member 62 elastically supports the second moving member 61. As such, the second elastic member 62 pushing the second moving member 61 so that the second moving member 61 can move the user tray C in the direction (Y arrow direction) where the second position member 3 has been installed.

One side of the second elastic member 62 is supported on the plate, and the other side can support the second moving frame 611.

The second correcting unit 6 can include at least one or more second elastic member 62. If the second correcting unit 6 include a plurality of second elastic members 62, the second elastic members 62 can move the second moving member 61 by the same length as a whole by giving constant pressure to the second moving frame 611.

The second elastic member 62 and the first elastic member 52 can be a spring having predetermined elastic force.

The first correcting unit 5 and the second correcting unit 6 can move the user tray C in a direction that is perpendicular to each other, respectively. That is, the first correcting unit 5 and the second correcting unit 6 can push the third side C3 and the fourth side C4, which are perpendicular to each other, of user tray C, respectively.

The operating unit 7 can operate the first correcting unit 5 and the second correcting unit 6. As such, the first correcting unit 5 and the second correcting unit 6 can move the user tray C to the accurate position.

Hence, the apparatus for correcting position of the user tray 1 can operate the first correcting unit 5 and the second correcting unit 6 by one operating unit 7, so the apparatus is made of a simple structure, and can move the user tray C to the accurate position.

Further, the apparatus for correcting position of the user tray 1 can move the user tray C to the accurate position using only one power source, thereby reducing manufacturing costs and maintenance costs.

The operating unit 7 is coupled to the plate 4, and is movable on the plate 4. As the operating unit 7 is moved on the plate 4, the first correcting unit 5 and the second correcting unit 6 can be operated.

The operating unit 7 can be coupled to the lower side of the plate 4.

The operating unit 7 may include one among a guide block and a guide rail, and the plate 4 may include the other.

The operating unit 7 can be coupled to a rod 8a of a cylinder 8, and can be movable on the plate 4 as the rod 8a of the cylinder 8 moves.

The cylinder may be a pneumatic cylinder or a hydraulic cylinder.

The operating unit 7 may include a first operating unit 71 and a second operating unit 72.

The first operating unit 71 can be coupled to the plate 4, and can be movable on the plate 4. and the first operation unit 71 can operate the first correcting unit 5.

The first operating unit 71 operates the first correcting unit 5 so that the second operating unit 72 can operate the second correcting unit 6.

The first operating unit 71 can be coupled to the lower side of the plate 4. The first operating unit 71 includes one among a guide block and a guide rail, and the plate 4 can include the other.

The first operating unit 71 includes at least one or more protruding member 711 that rotates the first moving member 51.

The protruding member 711 is projected in the operating plate 71a of the first operating unit 71. The protruding member 711 can be projected in the direction where the first moving member 51 is positioned.

As such, when the rotating member 513 is supported by the protruding member 711, the first moving member 51 can be rotated in a direction where the first contacting member 512 goes away from the plate 4.

When the rotating member 513 is supported by the portion where the protruding member 711 is not formed in the operating plate 71a, the first moving member 511 can be rotated in the direction where the first contacting member 512 comes to contact the third side C3 of the user tray C.

The first moving member 51 can be elastically connected to the plate 4 by the first elastic member 52. The first elastic member 52 is stretched when the rotating member 513 is supported on the protruding member 711. The first elastic member 52 is compressed when the rotating member 513 is supported on a portion where the protruding member 711 is not formed in the operating plate 71a. As such, the first moving member 51 can be rotated.

Hence, the first moving member 51 can move the user tray C so that the first side C1 of the user tray is supported on the first position member 2 by the elastic force of the first elastic member 52, so the damage of the user tray C by excessive force given to the user tray C can be prevented.

The second operating unit 72 is coupled to the plate 4, can be movable on the plate 4. The second operating unit 72 can operate the second correcting unit 6, being interlocked with the first operating unit 71.

The second operating unit 72 can be coupled to the lower side of the plate 4. The second operating unit 72 can include one among a guide block or a guide rail, and the plate 4 can include the other.

The second operating unit 72 move the second moving member 61, being interlocked with the first operating unit 71.

The second operating unit 72 can move the second moving member 61 in the direction (the opposite direction of Y arrow) that goes away from the second position member 3. The second operating unit 72 can move the second moving member 61 in the direction (Y arrow direction) where the second position member 3 has been installed.

The second operating unit 72 can move the second moving member 61 in the direction (the opposite direction of Y arrow) that goes away from the second position member 3 by pushing the second moving member 61. The second operating unit 72 can move the second moving member 61 in the direction (Y arrow direction) where the second position member 3 has been installed by removing the force that has pushed the second moving member 61.

The second moving member 61 can be elastically supported by the second elastic member 62. The second elastic member 62 is compressed when the second operating unit 72 gives force to the second moving member 61, and is stretched by elastic force when the force is removed. As such, the second moving member 61 can be movable.

Hence, the second moving member 61 can move the user tray C so that the second side C2 of the user tray C is supported on the second position member 3 by elastic force of the second elastic member 62, so the damage of the user tray C by excessive force given to the user tray C can be prevented.

The first operating unit 71 and the second operating unit 72 can be integrally formed, so when the first operating unit 71 is moved as the load 8a of the cylinder 8 is moved, the second operating unit 72 can also be moved together.

However, the user tray C can be received on the plate 4 in such a manner that the user tray C is separated from the second position member 3 and the first position member 2 by respective distances.

Here, in order to more efficiently move the user tray C to the accurate position, the first operating unit 71 and the second operating unit 72 can be separated from each other as the first operating unit 71 and second operating unit 72 is moved on the plate 4.

As the first operating unit 71 is moved on the plate 4, the second operating unit 72 can operate the second correcting unit 6.

The first operating unit 71 can move the second operating unit 72 by giving force to the second operating unit 71 as being moved on the plate 4, can move the second operating unit 72 by removing the force.

Specifically, when the first operating unit 71 is moved in the direction where the second operating unit 72 has been positioned, the first operating unit 71 can push and move the second operating unit 72. when the first operating unit 71 is moved in the opposite of the direction where the second operating unit 72 has been positioned, the second operating unit 72 can move by the second elastic member 62.

The movement of the second operating unit 72 stops when the second side C2 of the user tray C is supported on the second position member 3. The first operating unit 71 continues to move until the first side C1 of the user tray C is supported on the first position member 2, so the first operating unit 71 continues to move after the first operating unit 71 and the second operating unit 72 is separated each other.

That is, the first operating unit 71 and the second operating unit 72 can be moved by different distances. As such, the first moving member 51 and the second moving member 61 can move the user tray C by different distances, thereby efficiently moving the user tray C to the accurate position.

As such, even though the user tray C is separated from the first position member 2 and the second position member 3 by different distances, when the user tray C is received on the plate 4, the apparatus for correcting position of the user tray 1 can move the user tray C to the accurate position.

Further, even though the size of the user tray C is changed within a certain range by the change of the type of the packaged chips, the apparatus for correcting position of the user tray 1 can move the changed user tray C to the accurate position without re-manipulation.

Hereinafter, the operation in the case where the first operating unit 71 and the second operating unit 72 are coupled to the plate 4, and can be separated from each other while moving on the plate 4 will be described with reference to the attached drawings.

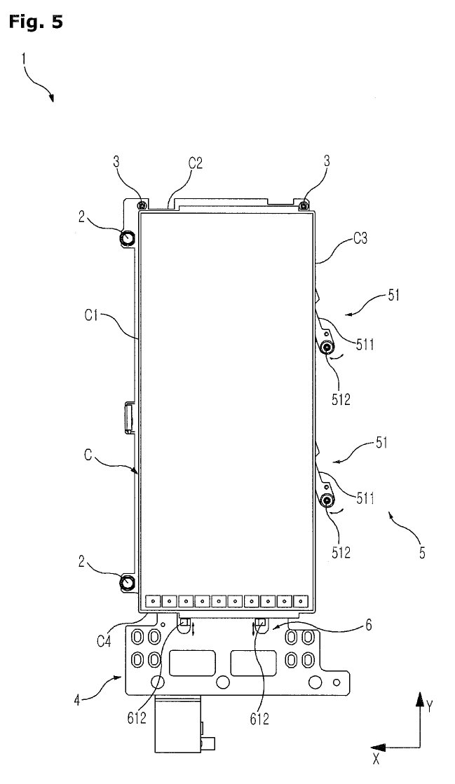

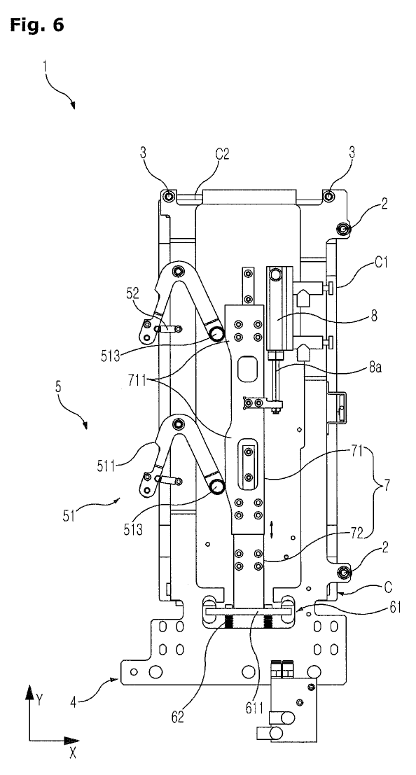

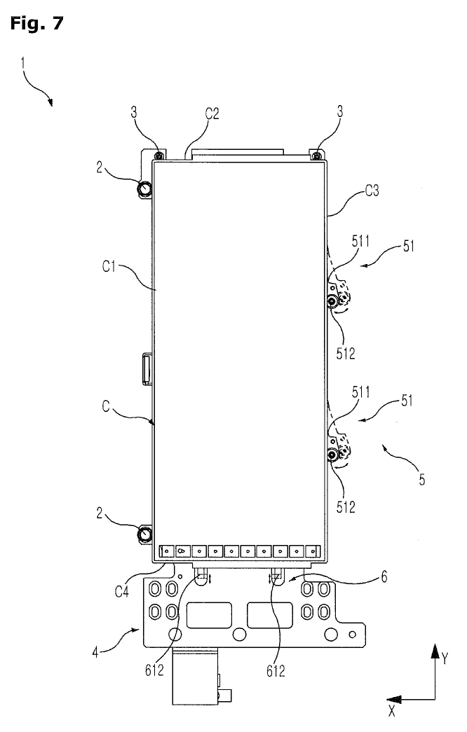

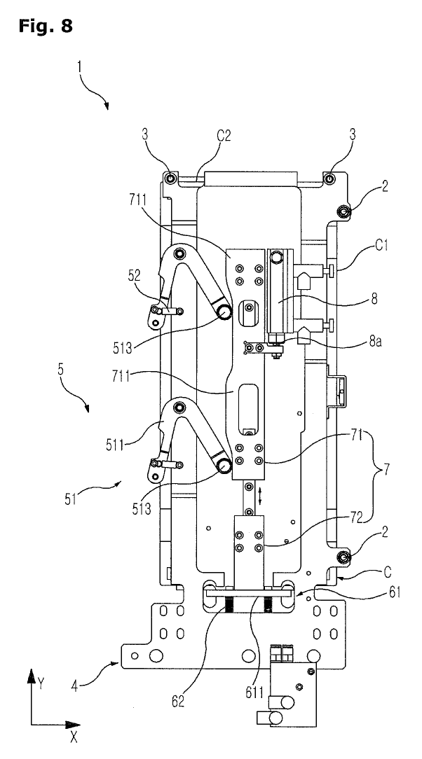

FIG. 5 is a plane view illustrating the state before an apparatus for correcting position of a user tray according to the present invention corrects the position of the user tray. FIG. 6 illustrates the lower side of FIG. 5. FIG. 7 is a plane view illustrating the state where an apparatus for correcting position of a user tray according to the present invention has corrected the position of the user tray. FIG. 8 illustrates the lower side of FIG. 7.

Referring to FIGS. 5 and 6, when the first operating unit 71 is moved in the direction where the second operating unit 72 is positioned, the first moving member 51 is rotated in a direction where the first contacting member 512 goes away from the plate 4 as the rotating member 513 is supported on the protruding member 711 of the first operating unit 71. Here, the first elastic member 52 is stretched.

The first operating unit 71 pushes the second operating unit 72, and the second operating unit 72 moves the second moving member 61 in a direction (the opposite direction of Y arrow) where the second contacting member 612 goes away from the second position member 3. Here, the second elastic member 62 is compressed.

In such a state, the user tray C can be received on the plate 4 without being disturbed by the first moving member 51 and the second moving member 61.

Referring to FIGS. 7 and 8, in the state where the user tray C is received on the plate 4, when the first operating unit 71 moves in the opposite of the direction where the second operating unit is positioned, the rotating member 51 is supported on the portion where the protruding member 711 has not been formed in the first operating unit 71. As such, the first moving member 51 is rotated in a direction where the first contacting member 512 comes to contact the third side C3 of the user tray C. Here, the first elastic member 52 is restored to the original form as the first elastic member 52 is compressed by elastic force.

As such, the user tray C is moved in a direction where the first position member 2 has been installed by the push of the first contacting member 512. The movement of the user tray C stops when the user tray C is supported on the first position member 2.

The second operating unit 72 removes the force that has been given to the second moving member 61 as the force that has been given to the first operating unit 71 is removed.

As such, the second moving member 61 is moved in a direction where the second position member 3 has been installed, and the second contacting member 612 moves the user tray C in a direction where the second position member 3 has been installed by pushing the fourth side C4 of the user tray C. Here, the second elastic member 62 is restored to the original form as the second elastic member 62 is stretched by elastic force.

The movement of the user tray C stops when the user tray C is supported on the second position member 3 by the push of the second contacting member 612.

When the user tray C is supported on the second position member 3, the movement of the second moving member 61 and the second operating unit 72 stops. And, the first operating unit 71 continues to move until the user tray C is supported on the first position member 2, so the first operating unit 71 and the second operating unit 72 become separated from each other.

The first side C1, the second side C2, the third side C3 and the fourth side C4 of the user tray C are supported on the first position member 2, the second position member 3, the first moving member 51 and the second moving member 61, respectively, so the position of the user tray C is corrected to a position where the picker system can be stably perform the loading process and unloading process.

Hereinafter, an exemplary embodiment of a test handler according to the present invention including the above-described apparatus for correcting position of a user tray will be described in detail with reference to the attached drawings.

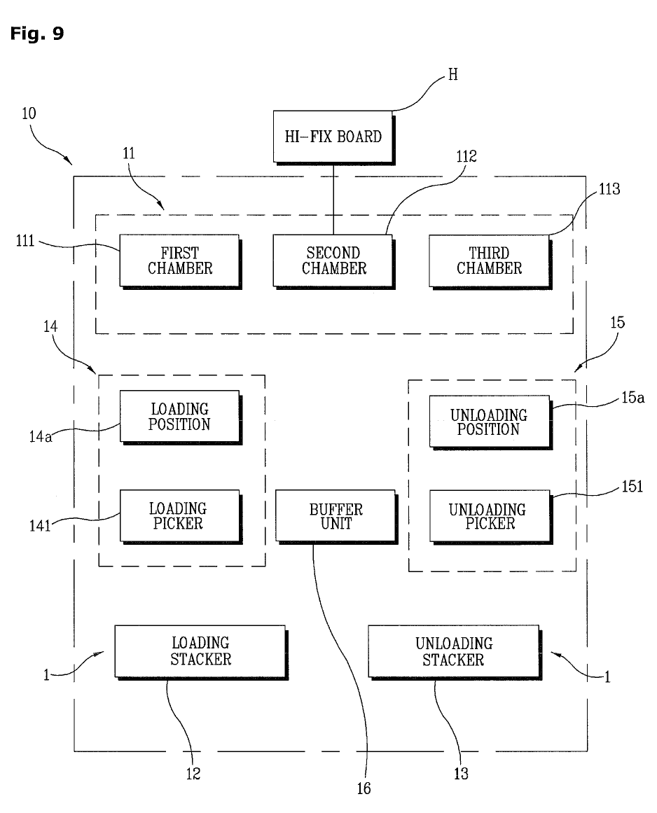

FIG. 9 is a block diagram illustrating the configuration of a test handler according to the present invention.

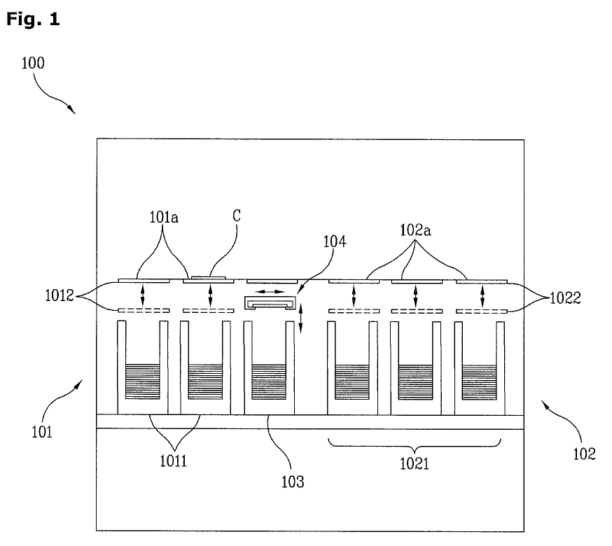

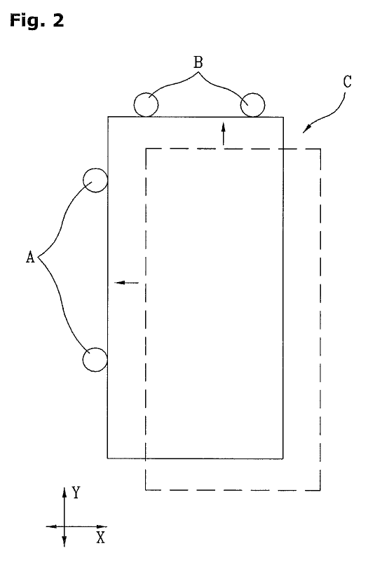

Referring to FIGS. 1 to 9, a test handler 10 according to the present invention includes a chamber system 11, a loading stacker 12, a unloading stacker 13, a loading unit 14, an unloading unit 15 and a buffer unit 16.

The chamber system 11 includes a first chamber 111, a second chamber 112 and a third chamber 113.

Within the first chamber 111, the packaged chips to be tested, contained in the test trays T, are heated or cooled to a testing temperature, which is predetermined depending upon a user's quality requirements. The test tray T is moved forward by a specific distance within the first chamber 111 as the heating or cooling occurs. After the packaged chips are heated or cooled to a testing temperature, a test tray T is transferred from the first chamber 111 into the second chamber 112.

Within the second chamber 112, the packaged chips in the test tray T are brought into contact with sockets of a hi-fix board H to receive the electrical tests. The test board H is coupled to the second chamber 112. After the packaged chips are all tested by a tester, the test tray T is transferred from the second chamber 112 into the third chamber 113.

Within the third chamber 113, the tested packaged chips contained in the test tray T are cooled or heated to room temperature. The test trays T are moved forward by a specific distance with the third chamber 113 as the heating or cooling occurs. After the packaged chips are cooled or heated to room temperature, the test tray T is transferred from the third chamber 113 to the unloading unit 15.

The first, second, and third chambers 111, 112, and 113 may be arranged in a row in the horizontal direction, in this order. In this arrangement, a plurality of the second chambers 112 may be provided in a column. In other words, one second chamber 112 may be located over another second chamber 112.

The first, second, and third chambers 111, 112, and 113 may also be arranged in a column in the vertical direction, in this order, with the second chamber 112 in between.

The loading stacker 12 stores a plurality of user trays C containing packaged chips to be tested. The apparatus for correcting position of the user tray 1 is installed in the loading stacker 12.

The unloading stacker 13 stores a plurality of user trays containing tested packaged chips. The apparatus for correcting position of the user tray 1 is installed in the unloading stacker 13. The tested packaged chips are received in the user trays C positioned in different positions by grades.

The loading unit 14 puts the packaged chips to be tested in the test tray, and includes a loading picker 141.

The loading picker 141 moves in X-axis and Y-axis directions. The loading picker 141 also ascend and descend. The loading picker 141 includes a plurality of nozzles that can absorb packaged chips.

The loading picker 141 picks up packaged chips to be tested from the user tray C positioned in the loading stacker 12, and puts the chips in the test tray positioned in the loading position 14a, which is the loading process.

The test handler 10 may include a plurality of the loading pickers 141 so that time that takes in the loading process may be reduced.

The loading-process-completed test tray is transferred from the loading position 14a to the first chamber 111.

The unloading unit 15 classifies tested packaged chips contained in the test tray by grades according to the test result. The unloading unit 15 includes an unloading picker 151.

The unloading picker 151 moves in X-axis and Y-axis directions. The unloading picker 151 also ascend and descend. The unloading picker 151 includes a plurality of nozzles that can absorb packaged chips.

The unloading picker 151 separates tested packaged chips from the test tray positioned in the unloading position 15a, and puts the separated packaged chips in the user tray C positioned in the unloading stacker 13 which is the unloading process.

The unloading picker 151 can put tested packaged chips in the user trays C positioned in different positions by grades according to the test result.

The test handler 10 can include a plurality of the unloading pickers 151 so that time that takes in the unloading process may be reduced.

The test tray that gets empty by the completion of the unloading process is transferred from the unloading position 15a to the loading position 14a.

The buffer unit 16 can temporarily contain packaged chips.

The buffer unit 16 may be installed to be used in at least one of the loading process and the unloading process.

If the buffer unit 16 is installed to be used in the loading process, the loading picker 141 can pick up packaged chips to be tested from the user tray C positioned in the loading stacker 12, and can put the packaged chips to be tested in the test tray positioned in the loading position via the buffer unit 16.

If the buffer unit 16 is installed to be used in the unloading process, the unloading picker 151 can separate tested packaged chips from the test tray positioned in the unloading position 15a, and can put the tested packaged chips in the user tray C positioned in the unloading stacker 13 via the buffer unit 16.

Hereinafter, another embodiment of a test handler that is constituted as described above will be described in detail with reference to the attached drawings.

Here, a test handler according to another embodiment has the configuration similar to that of the above-described test handler, so only differences in the configuration will be described in the following.

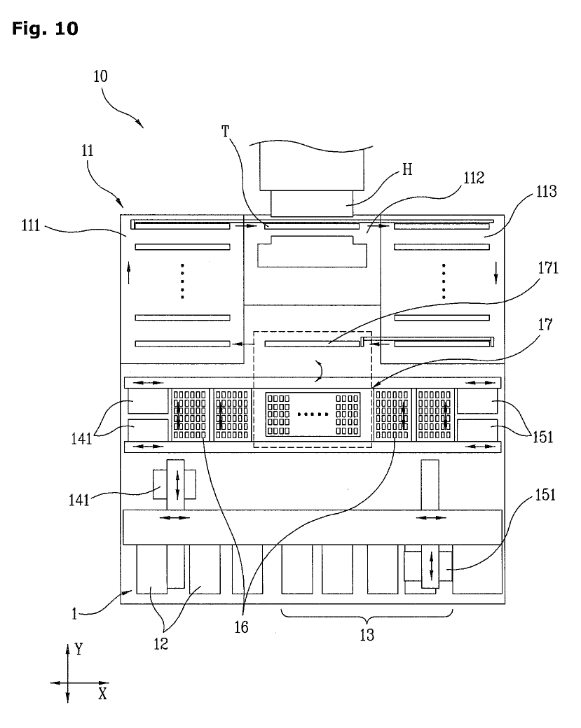

FIG. 10 is a plane view illustrating a test handler according to another embodiment of the present invention.

Referring to FIGS. 9 and 10, a test handler 10 according to another embodiment of the present invention includes an exchanging unit 17 that is not included in the test handler 10 of FIG. 9.

The exchanging unit 17 exchanges a test tray T containing packaged chips to be tested and a test tray T containing tested packaged chips with the chamber system 11.

The test tray T containing packaged chips to be tested is transferred from the exchanging unit 17 to the chamber system 11, and the test tray T containing tested packaged chips is transferred from the chamber system 11 to the exchanging unit 17.

In the exchanging unit 17, the process of putting packaged chips to be tested in the test tray T and the process of separating tested packaged chips from the test tray T are performed. Here, the process of putting packaged chips to be tested in the test tray T is part of the loading process, and the process of separating the tested packaged chips from the test tray T is part of the unloading process. The exchanging unit 17 includes the loading position 14a and the unloading position 15a, and implements the loading position 14a and unloading position in one position.

The exchanging unit 17 may further include a rotating unit 171.

The rotating unit 171 rotates a test tray containing the packaged chips to be tested from a horizontal position to a vertical or upright position.

The test tray T remains in the upright position during its transfer within the chamber system 11.

The rotating unit 161 may rotate an upright-positioned test tray containing tested packaged chips from a vertical position to a horizontal position. The test tray T remains in the horizontal position while the tested packaged chips are separated from it and then the new packaged chips to be tested are received into it.

It should be understood by those of ordinary skill in the art that various replacements, modifications and changes may be made in the form and details without departing from the spirit and scope of the present invention as defined by the following claims. Therefore, it is to be appreciated that the above described embodiments are for purposes of illustration only and are not to be construed as limitations of the invention.

What is claimed is:

1. An apparatus for correcting position of a user tray, the apparatus comprising:
at least one first position member and at least one second position member that determine position of a user tray;
a plate where the user tray is received;
a first correcting unit that moves the user tray in a direction where the first position member is installed;
a second correcting unit that moves the user tray in a direction where the second position member is installed; and
an operating unit that operates the first correcting unit and the second correcting unit.

2. The apparatus of claim 1, wherein the operating unit comprises:
a first operating unit that is coupled to the plate, and wherein the first operating unit operates the first correcting unit; and
a second operating unit that is coupled with the plate, and wherein the second operating unit operates the second correcting unit, being interlocked with the first operating unit.

3. The apparatus of claim 2, wherein the first operating unit and the second operating unit can be separated while moving on the plate, and wherein the second operating unit operates the second correcting unit while moving along the first operating unit.

4. The apparatus of claim 2, wherein the first correcting unit comprises:
at least one first moving member that is coupled to the plate, and wherein at least one first moving member can be rotated on the plate; and
a first elastic member that elastically connects the first moving member to the plate.

5. The apparatus of claim 4, wherein the first moving member comprises:
a first moving frame that is coupled to the plate, and wherein the first moving frame can be rotated on the plate;
a first contacting member that is coupled to one end of the first moving frame, and wherein the first contacting member moves the user tray according to the rotation of the first moving frame; and
a rotating member that is coupled to the other end of the first moving frame, and wherein the rotating member can be rotated on the other end of the first moving frame and contacts the first operating unit.

6. The apparatus of claim 5, wherein the first contacting member is coupled to one end of the first moving frame, and wherein the first contacting member can be rotated on the one end of the first moving frame.

7. The apparatus of claim 4, wherein the first operating unit comprises at least one protruding member that rotates the first moving member.

8. The apparatus of claim 2, wherein the second correcting unit comprises:
a second moving member that is moved in a direction where the second position member is installed, and wherein the second moving member moves the user tray in a direction where the second position member is installed; and
at least one second elastic member that elastically supports the second moving member.

9. The apparatus of claim 8, wherein the second moving member comprises:
a second moving frame that is elastically supported by the second elastic member; and
at least one second contacting member that is projected in the second moving frame, and wherein the at least one second contacting member moves the user tray.

10. The apparatus of claim 8, wherein the second operating unit moves the second moving member, being interlocked with the first operating unit.

11. The apparatus of claim 1, wherein the first correcting unit and the second correcting unit move the user tray in a direction that is perpendicular to each other.

12. The apparatus of claim 1, wherein the operating unit is coupled to the plate, and wherein the operating unit is movable on the plate; and
wherein the first correcting unit and the second correcting unit are operated according to the movement of the operating unit.

13. A test handler comprising:
a loading stacker that a plurality of user trays containing packaged chips to be tested;
a loading unit that puts to-be-tested packaged chips in a test tray;
a chamber system where the packaged chips are brought into contact with a hi-fix board;
an unloading unit that classifies tested packaged chips contained in the test tray by grades according to the test result;
an unloading stacker that stores a plurality of user trays containing tested packaged chips; and
an apparatus for correcting position of a user tray installed in the loading stacker and the unloading stacker, respectively,
wherein the apparatus for correcting position of the user tray comprises:
at least one first position member and at least one second position member that determine position of a user tray;
a plate where the user tray is received;
a first correcting unit that moves the user tray in a direction where the first position member is installed;
a second correcting unit that moves the user tray in a direction where the second position member is installed; and
an operating unit that operates the first correcting unit and the second correcting unit.

14. The test handler of claim 13, wherein the operating unit comprises:
a first operating unit that is coupled to the plate, and wherein the first operating unit operates the first correcting unit; and
a second operating unit that is coupled with the plate, and wherein the second operating unit operates the second correcting unit, being interlocked with the first operating unit.

15. The test handler of claim 14, wherein the first operating unit and the second operating unit can be separated while moving on the plate, and wherein the second operating unit operates the second correcting unit while moving along the first operating unit.

16. The test handler of claim 13, wherein the first correcting unit comprises:
at least one first moving member that is coupled to the plate, and wherein at least one first moving member can be rotated on the plate; and
a first elastic member that elastically connects the first moving member to the plate.

17. The test handler of claim 13, wherein the second correcting unit comprises:
a second moving member that is moved in a direction where the second position member is installed, and wherein the second moving member moves the user tray in a direction where the second position member is installed; and
at least one second elastic member that elastically supports the second moving member.

18. The test handler of claim 17, wherein the second operating unit moves the second moving member, being interlocked with the first operating unit.

19. The test handler of claim 13, wherein the first correcting unit and the second correcting unit move the user tray in a direction that is perpendicular to each other.

20. The test handler of claim 13, wherein the operating unit is coupled to the plate, and wherein the operating unit is movable on the plate; and
wherein the first correcting unit and the second correcting unit are operated according to the movement of the operating unit.
